(19) United States
(12) Patent Application Publication
(10) Pub. No.: US 2017/0150637 A1
(43) Pub. Date: May 25, 2017

(54) SLOTTED CROSS-MEMBER

(71) Applicant: MacLean Power, LLC, Fort Mill, SC (US)

(72) Inventor: Aaron Callahan, Fort Mill, SC (US)

(73) Assignee: Maclean Power, LLC, Fort Mill, SC (US)

(21) Appl. No.: 15/355,989

(22) Filed: Nov. 18, 2016

Related U.S. Application Data
(60) Provisional application No. 62/257,538, filed on Nov. 19, 2015.

(51) Int. Cl. H05K 7/18; F16M 13/02

(52) U.S. Cl. CPC H05K 7/183; F16M 13/02

(57) ABSTRACT

A cross-member for supporting electrical equipment above the ground, where the cross-member includes a slot to accept a bolt used to secure the electrical equipment to the cross-member, where the slot allows the bolt to be inserted into the cross-member after the electrical equipment is placed on the cross-member.

### RELATED APPLICATIONS

The present patent document claims the benefit of the filing date under 35 U.S.C. §119(e) of Provisional U.S. patent application Ser. No. 62/257,538, filed Nov. 19, 2015, which is hereby incorporated by reference.

### FIELD

The embodiments relate generally to a cross-member for supporting electrical equipment. They relate particularly to a cross-member with a recessed slot to facilitate securing the electrical equipment on the cross-member.

### BACKGROUND

Traditional cross-members for supporting electrical equipment include bolts inserted in tracks in the cross-members. The bolts are inserted prior to electrical equipment being placed on the cross-member. Accordingly, bolt holes in the electrical equipment must be aligned with the bolts and then the electrical equipment can lowered onto the bolts and the cross-member. Aligning the bolt holes in the electrical equipment with the bolts is very difficult because there are often four bolts to align, the electrical equipment is often heavy, sometimes weighing thousands of pounds, and is located at elevated positions. Additionally, aligning the bolt holes in the electrical equipment with the bolts creates a safety concern because the lineman installing the electrical equipment are located above the ground and must manually align four bolts as the electrical equipment is moved into place.

### BRIEF SUMMARY

In one embodiment, a cross-member for supporting electrical equipment comprises a longitudinal member with a first wall, a second wall, and a first base extending between the first wall and the second wall, where the first wall, the second wall, and the first base extend along an entire length of the cross-member, and a protrusion extending from the first base into a space between the first wall and the second wall, where the protrusion includes a third wall, a fourth wall, and second base, where the protrusion includes an opening in a direction away from the space between the first wall and the second wall, and at least one slot in the second base that extends longitudinally along a portion of the second base, where a width of the at least one slot is less than a width of the second base, where a length of the at least one slot is greater than the width of the at least one slot, where the at least one slot is configured to accept a bolt after electrical equipment is placed on the cross-member.

In another embodiment, a method of installing electrical equipment on a cross-member comprises providing a cross-member comprising a longitudinal member having a first wall, a second wall, and a first base extending between the first wall and the second wall, where the first wall, the second wall, and the first base extend along the entire length of the cross-member, the cross member further comprising a protrusion extending from the first base into a space between the first wall and the second wall, where the protrusion includes a third wall, a fourth wall, and second base, where the protrusion includes an opening in a direction away from the space between the first wall and the second wall, the protrusion comprising at least one slot in the second base that extends longitudinally along a portion of the second base, where a width of the at least one slot is less than a width of the second base, where a length of the at least one slot is greater than the width of the at least one slot; and aligning a bolt hole in a base of electrical equipment with the at least one slot; placing the electrical equipment on the cross-member such that the base of the electrical equipment rests on the first base of the cross member; and inserting a bolt through the bolt hole and the at least one slot.

Other systems, methods, features and advantages of the invention will be, or will become, apparent to one with skill in the art upon examination of the following figures and detailed description. It is intended that all such additional systems, methods, features and advantages be included within this description, be within the scope of the invention, and be protected by the following claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is a side view of a cross-member.

FIG. 2 is a perspective view of a cross-member.

FIG. 3 is a side view of a cross-member.

FIG. 4 is a perspective view of a cross-member.

FIG. 5 is a perspective cross-sectional view of a cross-member installation.

### DETAILED DESCRIPTION OF THE DRAWINGS

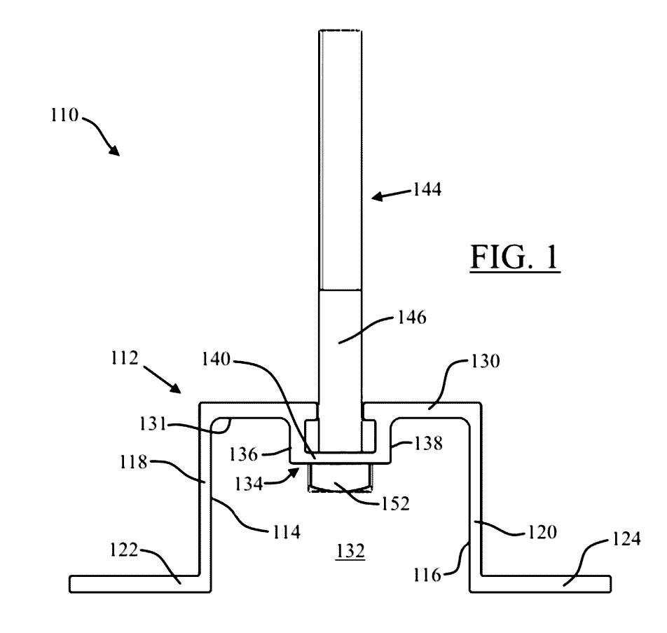

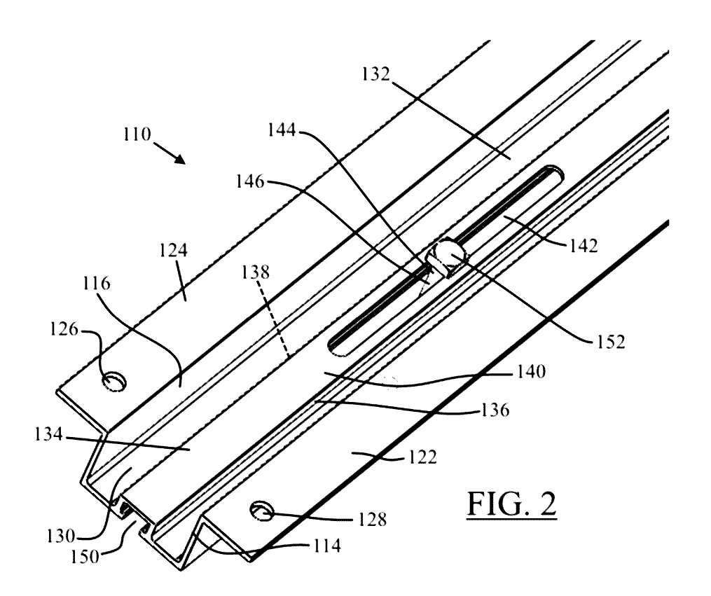

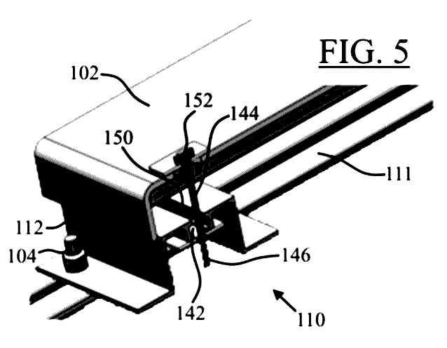

Referring to FIGS. 1-2, a cross-member 110 for supporting electrical equipment is provided. The cross member 110 may comprise a longitudinal member 112 with a first wall 114 and a second wall 116. As best shown in FIG. 1, the first wall 114 may be located on a surface of a first leg 118, and the second wall 116 may be located on a second leg 120. The legs 118 and 120 may be configured to contact or otherwise interact with a rack or other suitable system for supporting the electrical equipment (shown in FIG. 5). In some embodiments, the legs 118 and 120 respectively comprise the depicted flat portions 122 and 124 with bores 126 and 128 (shown in FIG. 2), which may facilitate the attachment of the longitudinal member 112 to other support equipment or structure.

As shown in FIG. 1, a first base 130 may extend between the first wall 114 and the second wall 116. The first wall 114, the second wall 116, and the first base 130 may extend along an entire length of the cross-member 110. The first base 130 may comprise a first surface 131 that is substantially perpendicular to the first wall 114 and/or the second wall 116. The first surface 131 may be adjacent to a space 132 at least partially defined by the first wall 114, second wall 116, and/or the first base 130.

The cross-member 110 may comprise a protrusion 134 extending from the first base 130 into the space 132. In the depicted embodiment, the protrusion 134 has a third wall 136 and a fourth wall 138. The third wall 136 may be parallel or approximately parallel to, and face towards, the first wall 114. Similarly, the fourth wall 138 may be parallel or approximately parallel to, and face towards, the second wall 116. A second base 140 may extend between the third wall 136 and the fourth wall 138. In some embodiments, and as depicted in FIGS. 1-2, the protrusion 134 including the third wall 136, the fourth wall 138, and the second base 140 may extend along the entire length of the cross-member 110.

As best shown by FIG. 2, at least one slot 142 may be formed in the second base 140. The slot 142 may comprise a length that extends longitudinally along a portion of the second base 140. A width of the slot 142 may be less than a width of the second base 140. The second base 140 may comprise more than one slot. In some embodiments, each of the slots may have identical or similar dimensions.

The slot 142 may be configured to accept a bolt 144, for example after electrical equipment is placed on the cross-member 110. As depicted in FIG. 1, the width of the slot 142 may be wider than the diameter of the elongated body portion 146 of the bolt 144, but smaller than the minimum cross-sectional size of a nut 148 (not shown) corresponding to the bolt 144. This embodiment is advantageous where the cross member 110 and corresponding equipment are designed such that a nut 148 (not shown) can be joined to the bolt 144 at a location within the space 132. In some instances (and as shown in FIGS. 1-4), head 152 of the bolt 144 may be alternatively located within the space 132, and therefore the width of the slot 142 may be larger than the diameter of the elongated body portion 146 of the bolt 144 but smaller than the minimum cross-sectional dimension of the head of the bolt 144.

In some embodiments, including the embodiment shown in FIG. 1, the first base 130 may comprise an opening 150. The opening 150 may be located opposite the slot 142, and as depicted, may extend the entire length of the cross-member 110. Alternatively, the opening 150 may be formed along only a portion of the first base 130 opposite of the slot 142. Like the slot 142, the opening 150 preferably has a width greater than the diameter of the elongated body portion 146 of the bolt 144 such that the opening 150 can accept the bolt 144.

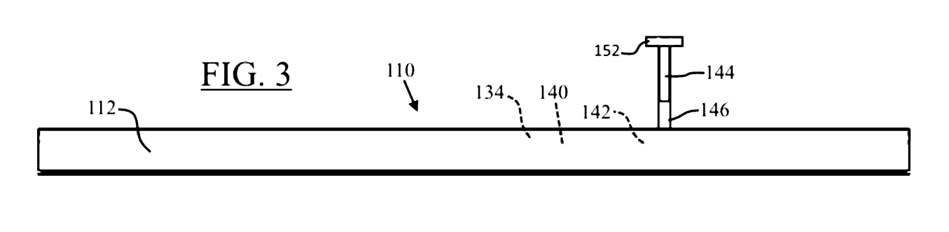

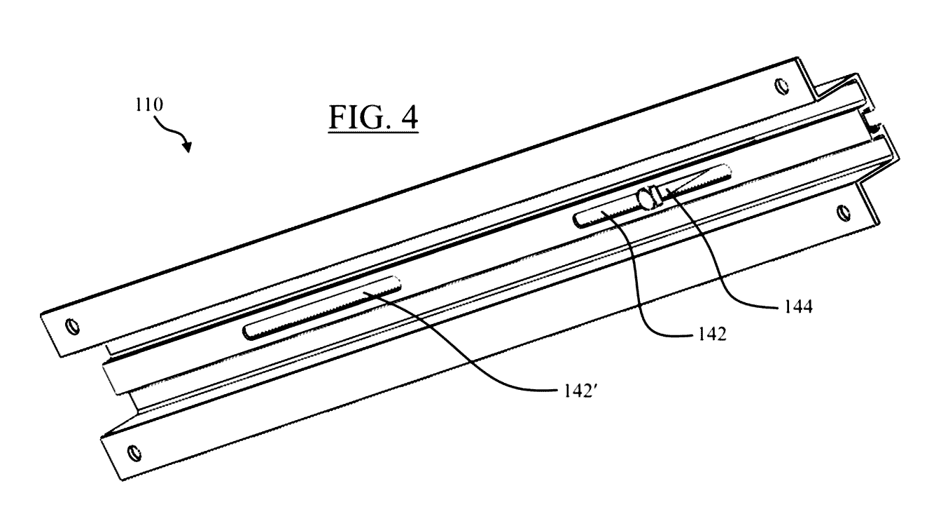

The above-described embodiments are advantageous when installing (e.g., securing) electrical equipment to the cross-member 110. Referring to FIG. 3, the cross-member 110 comprises the protrusion 134 with the second base 140, and a slot 142 in the second base 140. This configuration allows a bolt 144 to be lowered from above such that the elongated body portion 146 may be accepted by the slot 142. This may allow a fastener (such as the depicted nut 148) to be tightened from the bottom of the longitudinal member 112 from within the space 132 (see FIG. 1). Advantageously, this embodiment may allow the bolt 144 to be placed from above after the placement of the electrical equipment on the cross-member 110 and prior to the tightening of the nut 148 from below. This may allow the electrical equipment to be located on the cross-member 110 without consideration of the location of a pre-placed fastener, which may increase the safety and efficiency of installing the electrical equipment. Additionally or alternatively, this configuration allows a bolt 144 to be inserted in slot 142 from below, as shown in FIG. 4. Inserting bolt 144 into slot 142 from below also may allow the bolt 144 to be placed after the placement of the electrical equipment on the cross-member 110 and prior to securing the bolt from above, such as with a nut 148. Bolt 144 may be inserted in slot 142 from above or below cross-member 110 after the electrical equipment is placed on cross-member 110. Additional components may be included to secure bolt 144 to cross-member 110, such as a washer (not shown) that holds the bolt 144 and prevents rotation of bolt 144.

The method of securing bolt 144 and direction of inserting bolt 144 in slot 142 may vary depending on the application. Securing methods may include, for example, threaded fasteners, such as nuts, threaded elements of cross member 110, threaded elements of other supporting equipment, and inserting pins perpendicular to the bolt 144, as well as other fasteners.

Referring to FIG. 4, multiple slots 142, 142′ may be formed in the second base 140. This may be advantageous when corresponding electrical equipment requires securement at multiple locations (thereby requiring multiple fasteners). In other embodiments, the longitudinal member 112 may have more than two slots 142. The slots 142, 142′ may have substantially identical dimensions, particularly when they are configured to interact with substantially identical fasteners. In other embodiments, the dimensions of the slots 142, 142′ may be different. For example, in some instances, the location of electrical equipment placed on the cross-member 110 may be particularly sensitive, and therefore one slot may have relatively small dimensions to precisely locate one fastener connecting one connection point of the electrical equipment to the cross-member 110, while a second slot may have relatively larger dimensions, which may simplify the process of locating the second slot when placing the second fastener.

FIG. 5 shows a cross-sectional view of a cross-member installation in which a frame 102 corresponding to electrical equipment is attached to the cross-member 110. As shown, frame 102 is in contact with the longitudinal member 112, which is placed on a second perpendicular longitudinal member 111 (though this is not required in every embodiment). The longitudinal member 112 may be adjustable along the second longitudinal member 111, and may be secured in place by a fastener 104 when properly placed. The frame 102 may be lowered into contact with the longitudinal member 112. Frame 102 may be placed such that holes in the frame 102 correspond to the location of slots 142 in cross-member 110. After the frame 102 is placed in a suitable location, the bolt 144 may be lowered through the frame 102, and the elongated body portion 146 of the bolt 144 may be lowered through the opening 150 and may be accepted by the slot 142. In some embodiments, if further adjustment of the location of the frame 102 is required, the frame may move longitudinally along the longitudinal member 112 even after the bolt 144 is placed and prior to tightening a faster (e.g., a nut) to the bolt.

While this invention has been particularly shown and described with references to embodiments thereof, it will be understood by those skilled in the art that various changes in form and details may be made therein without departing from the spirit and scope of the invention as defined by the appended claims.

I claim:

1. A cross-member for supporting electrical equipment comprising:
a longitudinal member with a first wall, a second wall, and a first base extending between the first wall and the second wall, wherein the first wall, the second wall, and the first base extend along an entire length of the cross-member;
a protrusion extending from the first base into a space between the first wall and the second wall, wherein the protrusion includes a third wall, a fourth wall, and a second base, wherein the protrusion includes an opening in a direction away from the space between the first wall and the second wall;
at least one slot in the second base that extends longitudinally along a portion of the second base, wherein a width of the at least one slot is less than a width of the second base, wherein a length of the at least one slot is greater than the width of the at least one slot, wherein the at least one slot is configured to accept a bolt after electrical equipment is placed on the cross-member.

2. The cross-member of claim 1, wherein the at least one slot is configured to accept a bolt inserted into the at least one slot from the space between the first wall and the second wall after electrical equipment is placed on the cross-member.

3. The cross-member of claim 1, wherein the at least one slot is configured to accept a bolt inserted into the at least one slot from a side of the cross-member adjacent to the first base after electrical equipment is placed on the cross-member.

4. The cross-member of claim 1, further comprising attachment tabs extending from an end of the first wall and the second wall that is opposite the first base, wherein the attachment tabs are substantially perpendicular to the first wall and the second wall.

5. The cross-member of claim 4, further comprising a plurality of bores located in the attachment tabs.

6. The cross-member of claim 1, wherein the opening in the protrusion is narrower than the second base.

7. The cross-member of claim 1, wherein the first wall, second wall, third wall, and fourth wall are substantially parallel to each other.

8. The cross-member of claim 1, wherein the first base and the second base are substantially parallel to each other.

9. The cross-member of claim 1, wherein the first wall, second wall, third wall, and fourth wall are substantially perpendicular to the first base and the second base.

10. The cross-member of claim 1, wherein the at least one slot includes two slots, wherein the two slots are spaced apart.

11. The cross-member of claim 10, wherein the two slots have different dimensions.

12. The cross-member of claim 1, wherein the width of the at least one slot is less than a width of the opening in the protrusion.

13. The cross-member of claim 1, wherein the width of the at least one slot is substantially the same as a width of the opening in the protrusion.

14. The cross-member of claim 1, further comprising a bolt to secure electrical equipment on the cross-member.

15. The cross-member of claim 1, wherein the cross-member is configured to support a voltage regulator.

16. The cross-member of claim 1, wherein the cross-member is configured to support electrical equipment in an elevated position.

17. A method of installing electrical equipment on a cross-member, the method comprising:
providing a cross-member comprising a longitudinal member having a first wall, a second wall, and a first base extending between the first wall and the second wall, wherein the first wall, the second wall, and the first base extend along the entire length of the cross-member, the cross member further comprising a protrusion extending from the first base into a space between the first wall and the second wall, wherein the protrusion includes a third wall, a fourth wall, and a second base, wherein the protrusion includes an opening in a direction away from the space between the first wall and the second wall, the protrusion comprising at least one slot in the second base that extends longitudinally along a portion of the second base, wherein a width of the at least one slot is less than a width of the second base, wherein a length of the at least one slot is greater than the width of the at least one slot;
aligning a bolt hole in a base of electrical equipment with the at least one slot;
placing the electrical equipment on the cross-member such that the base of the electrical equipment rests on the first base of the cross member;
inserting a bolt through the bolt hole and the at least one slot.

18. The method of claim 17, wherein the at least one slot comprises a plurality of slots, the method further comprising the step of aligning a plurality of bolt holes in the base of electrical equipment with the plurality of slots.

19. The method of claim 17, wherein the bolt is inserted through the bolt hole and the at least one slot from above the base of the electrical equipment.

20. The method of claim 17, wherein the bolt is inserted through the bolt hole and the at least one slot from below the cross-member.

21. A cross-member for supporting equipment comprising:
a longitudinal member with a first wall, a second wall, and a first base extending between the first wall and the second wall, wherein the first wall, the second wall, and the first base extend along an entire length of the cross-member;
a protrusion extending from the first base into a space between the first wall and the second wall, wherein the protrusion includes a third wall, a fourth wall, and a second base, wherein the protrusion includes an opening in a direction away from the space between the first wall and the second wall;
at least one slot in the second base that extends longitudinally along a portion of the second base, wherein a width of the at least one slot is less than a width of the second base, wherein a length of the at least one slot is greater than the width of the at least one slot, wherein the at least one slot is configured to accept a bolt after equipment is placed on the cross-member.
